(19) United States
(12) Patent Application Publication
(10) Pub. No.: US 2015/0216074 A1
(43) Pub. Date: Jul. 30, 2015

(54) HEAT DISSIPATION PLATE

(71) Applicants: Noboru Nishihara, Tokyo (JP); Koichi Tatsuyama, Tokyo (JP); Hiroshi Mihara, Tokyo (JP)

(72) Inventors: Noboru Nishihara, Tokyo (JP); Koichi Tatsuyama, Tokyo (JP); Hiroshi Mihara, Tokyo (JP)

(73) Assignee: Mitsubishi Electric Corporation, Chiyoda-ku, Tokyo (JP)

(21) Appl. No.: 14/418,508

(22) PCT Filed: Aug. 2, 2012
(86) PCT No.: PCT/JP2012/069753

§ 371 Date: Jan. 30, 2015

(51) Int. Cl. H05K 7/20

(52) U.S. Cl. CPC H05K 7/2039

(57) ABSTRACT

A heat dissipation plate includes: a substantially rectangular heat transfer surface that comes in contact with an electronic component; a plurality of side walls that are provided respectively in four directions of the heat transfer surface; and a heat-dissipation base surface that is connected to the heat transfer surface via the side walls. The heat generated by the electronic component is received by the heat transfer surface, is transmitted from the heat transfer surface to the heat-dissipation base surface via the side walls, and is dissipated from the heat-dissipation base surface. A plurality of vents are provided on at least one of the side walls.

### FIELD

The present invention relates to a heat dissipation plate.

### BACKGROUND

Conventional heat dissipation structures for releasing heat generated from an electronic component mounted on a printed board are known in which a metal plate with good thermal conductivity is brought into contact with a heat-generating electronic component via a flexible thermally-conductive sheet and used as a heat dissipation plate.

In such a heat dissipation structure, when the height of the heat-generating electronic component is equal to or lower than the electronic components that are present therearound, interference or short circuiting with the heat dissipation plate may occur. Therefore, it is necessary to prevent interference with the peripheral electronic components. Consequently, notches or the like are made on the heat dissipation plate, which decreases the surface area of the heat dissipation plate, thereby decreasing heat dissipation performance.

Even when the height of the heat-generating electronic component is higher than the peripheral electronic components, heat-removing airflow still tends to become hindered depending on the distance between the heat dissipation plate and the peripheral electronic components, and the heat transferred from the electronic components that generate the heat to the heat dissipation plate is reabsorbed by the peripheral electronic components.

Similarly, even when the height of the heat-generating electronic component is higher than the peripheral electronic components, and when the insulation distance between the heat dissipation plate and the peripheral electronic components is not sufficient, the noise resistance of the electronic device decreases.

Therefore, as a first conventional technique to solve the problems described above, as described in Patent Literature 1, a projecting heat-transfer shape is provided that projects over a part of the heat dissipation plate by approximately the size of the heat-generating electronic component and is brought into contact with the heat-generating electronic component via a thermally-conductive sheet or the like in order to propagate heat over the entire heat dissipation plate, thereby performing heat dissipation and setting the distance between peripheral electronic components and the heat dissipation plate.

As a second conventional technique, as described in Patent Literature 1, there is a technique in which a projecting heat-transfer shape is made with the entire surface of the side walls on the windward and leeward sides being open by cutting and raising the heat dissipation plate in a U-shape or by bonding a U-shaped component thereto so as to generate heat-removing airflow in the projecting heat-transfer shape on an opposite side to the heat-generating electronic component.

As a third conventional technique, as described in Patent Literature 2, there is a technique for forming a projecting heat-transfer shape with the entire surface of the side walls on the windward and leeward sides being open by cutting and raising a part of the heat dissipation plate in a tongue shape so as to generate heat-removing airflow in the projecting heat-transfer shape on the opposite side to the heat-generating electronic component.

### CITATION LIST

Patent Literatures

Patent Literature 1: Japanese Patent Application Laid-open No. 2004-214401

Patent Literature 2: Japanese Patent Application Laid-open No. H9-8484

### SUMMARY

### Technical Problem

However, in the first conventional technique, the projecting heat-transfer shape of the heat dissipation plate acts as a barrier and forms a place where the heat-removing airflow is hindered and becomes an obstacle to improve the ventilation.

In the second and third conventional techniques, the channel size considerably decreases for propagating heat, which is transferred from the heat-generating electronic component to the projecting heat-transfer shape, over the entire heat dissipation plate; and it is difficult to improve the heat dissipation capacity because the propagating heat does not propagate over the entire heat dissipation plate.

The present invention has been made in view of the above problems, and an objective of the present invention is to provide a heat dissipation plate with stable performance by reducing interference and short-circuiting with peripheral electronic components, by reducing reabsorption of heat, and by reducing the occurrence of places where the airflow is hindered by effectively using the entire area for heat dissipation, thus effectively dissipating the heat of the electronic components, which increases the performance of the electronic components, and also provides a heat dissipation plate that can be downsized.

### Solution to Problem

To solve the problem and achieve the objective, the present invention relates to a heat dissipation plate that includes: a substantially rectangular heat transfer surface that comes in contact with a heat-generating component; a plurality of side walls that are provided respectively in four directions of the heat transfer surface; and a heat-dissipation base surface that is connected to the heat transfer surface via the side walls. Heat generated by the heat-generating component is received by the heat transfer surface, is transmitted from the heat transfer surface to the heat-dissipation base surface via the plurality of side walls, and is dissipated from the heat-dissipation base surface. A plurality of vents are provided on at least one of the side walls.

### Advantageous Effects of Invention

In the heat dissipation plate according to the present invention, channels are set that are required for the full propagation of the heat, which is received through the projecting heat-transfer shape, in four directions so that the entire surface area can be used for heat dissipation.

### BRIEF DESCRIPTION OF DRAWINGS

FIG. 1 is an exploded perspective view of a heat dissipation structure of a heat-generating component using a heat dissipation plate according to a first embodiment of the present invention.

FIG. 2 is a sectional view of the heat dissipation structure of the heat-generating component using the heat dissipation plate according to the first embodiment.

FIG. 3 is an exploded perspective view of a heat dissipation structure of a heat-generating component using a heat dissipation plate according to a second embodiment of the present invention.

FIG. 4 is a side view of the heat dissipation structure of the heat-generating component using the heat dissipation plate according to the second embodiment.

FIG. 5 is an exploded perspective view of a heat dissipation structure of a heat-generating component using a heat dissipation plate according to a third embodiment of the present invention.

FIG. 6 is a sectional view of the heat dissipation structure of the heat-generating component using the heat dissipation plate according to the third embodiment.

FIG. 7 is an exploded perspective view of a heat dissipation structure of a heat-generating component using a heat dissipation plate according to a fourth embodiment of the present invention.

FIG. 8 is an exploded perspective view of a heat dissipation structure of a heat-generating component using a heat dissipation plate according to a fifth embodiment of the present invention.

FIG. 9 is a perspective view of the heat dissipation structure of the heat-generating component using the heat dissipation plate according to the fifth embodiment.

FIG. 10 is a sectional view of the heat dissipation structure of the heat-generating component using the heat dissipation plate according to the fifth embodiment.

FIG. 11 is a sectional view of the bottom surface of a heat dissipation structure of a heat-generating component using a heat dissipation plate according to a sixth embodiment of the present invention.

FIG. 12 is an exploded perspective view of a heat dissipation structure of a heat-generating component using a heat dissipation plate according to a seventh embodiment of the present invention.

FIG. 13 is a perspective view of the heat dissipation structure of the heat-generating component using the heat dissipation plate according to the seventh embodiment.

FIG. 14 is a sectional view of the heat dissipation structure of the heat-generating component using the heat dissipation plate according to the seventh embodiment.

### DESCRIPTION OF EMBODIMENTS

Exemplary embodiments of a heat dissipation plate according to the present invention will be described below in detail with reference to the accompanying drawings. The present invention is not limited to the embodiments.

### First Embodiment

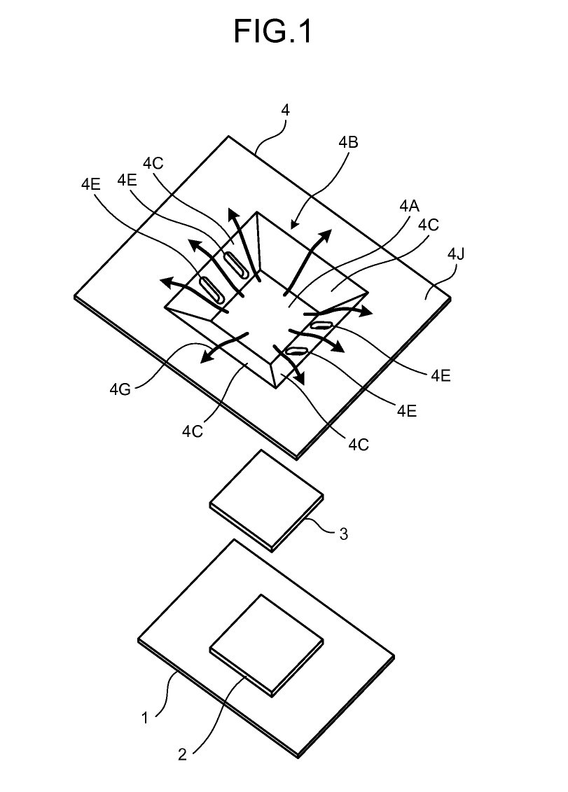

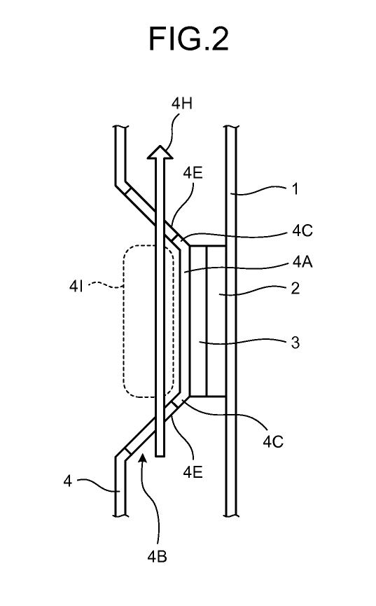

FIG. 1 is an exploded perspective view of a heat dissipation structure of a heat-generating component using a heat dissipation plate according to a first embodiment of the present invention. FIG. 2 is a sectional view of the heat dissipation structure of the heat-generating component using the heat dissipation plate according to the first embodiment. A projecting heat-transfer shape 4B of a heat dissipation plate 4 according to the first embodiment is used for a heat dissipation structure that dissipates heat generated by an electronic component 2 due to it being in contact with the electronic component 2 mounted on a printed board 1 via a thermally-conductive sheet 3. The electronic component 2 is a heat-generating component (for example, a circuit component such as a semiconductor device) that generates heat by energizing an electronic device to which the heat dissipation structure of the heat-generating component is applied. In FIG. 1, heat 4G, schematically represented by an arrow, is transferred from the electronic component 2 to a heat-transfer surface 4A of the heat dissipation plate 4 via the thermally-conductive sheet 3. The heat 4G then propagates from the heat-transfer surface 4A to a heat-dissipation base surface 4J. In FIG. 2, air 4H, schematically represented by an arrow, dissipates heat generated by the electronic component 2 by penetrating and flowing through the projecting heat-transfer shape 4B. That is, a situation where the heat 4G propagates over the entire heat dissipation plate 4 and the flow of the air 4H by convection are illustrated in FIGS. 1 and 2, respectively, to facilitate the explanations. Directions of the printed board 1 and the heat dissipation plate 4 are parallel to the gravitational direction at the time of natural convection; and at the time of forced convection, the directions thereof are not restricted to the gravitational direction.

The electronic component 2 is mounted on the printed board 1. The thermally-conductive sheet 3 is sandwiched between the heat-transfer surface 4A of the projecting heat-transfer shape 4B of the heat dissipation plate 4 and the electronic component 2. The thermally-conductive sheet 3 sandwiched between the heat dissipation plate 4 and the electronic component 2 deforms so as to be matched with irregularities on the surface of the heat dissipation plate 4 and the electronic component 2 and is firmly attached thereto, thereby increasing the heat transfer area when compared with a case where the electronic component 2 and the heat dissipation plate 4 are directly in contact with each other.

As illustrated in FIG. 1, two side walls facing each other of four side walls 4C of the projecting heat-transfer shape 4B of the heat dissipation plate 4 are provided with a plurality of vents 4E by punching or the like. The side walls 4C provided with these vents 4E are arranged on the windward side and the leeward side of the flow of the air 4H when convection is forced. In contrast, during natural convection, the side walls 4C provided with the vents 4E are arranged vertically in position.

The heat 4G generated by the electronic component 2 is transferred to the heat dissipation plate 4 via the thermally-conductive sheet 3 and is dissipated therefrom. To improve the heat dissipation capacity, it is effective if the heat 4G is propagated over the entire heat dissipation plate 4, i.e., the heat 4G is transferred from the heat-transfer surface 4A to the heat-dissipation base surface 4J. In the heat dissipation structure of the heat-generating component according to the present embodiment, the side walls 4C, which function as the channels required for transferring the heat 4G of the electronic component 2 received by the heat-transfer surface 4A to the heat-dissipation base surface 4J, are formed in four directions of the heat-transfer surface 4A; and thus heat can be transferred through portions other than the vents 4E in the side walls 4C.

When the width of the vent 4E is less than 2 millimeters, it is difficult for the air 4H to pass through the vents 4E by convection, and thus the width thereof is set to be equal to or larger than 2 millimeters. When the vent 4E is opened with an area equal to or less than 30% per one side wall 4C of the projecting heat-transfer shape 4B (in other words, when the value acquired by dividing “the sum total of the area of the vents 4E provided in one of the side walls 4C” by “the area of one side wall 4C before forming the vents 4E” becomes 0.3 or less), efficient heat dissipation can be performed because not only does the air 4H flow from the vents 4E to dissipate heat, but also the heat is transferred through the side walls 4C excluding the vents 4E and dissipated by the entire heat dissipation plate 4.

As illustrated in FIG. 2, by providing the vents 4E in the projecting heat-transfer shape 4B, the air 4H passes through the vents 4E and flows through a high-temperature portion 4I of the projecting heat-transfer shape 4B on the opposite side to the heat-generating electronic component 2 (a space surrounded by the heat-transfer surface 4A and the side walls 4C, which becomes a high temperature due to radiation or the like from the heat-transfer surface 4A and the side walls 4C). Therefore, much more heat can be removed from the heat dissipation plate 4, and the heat dissipation amount can be increased. Because the air 4H also flows to the leeward side of the projecting heat-transfer shape 4B, an effect of decreasing the occurrence of a place where the flow of the air after removing heat from the heat dissipation plate 4 is hindered can be acquired, thereby enabling an improvement of the heat dissipation capacity. That is, by providing the vents 4E in the side walls 4C on the windward side and the leeward side of the projecting heat-transfer shape 4B while securing the channels that are required for propagation of the heat 4G, heat dissipation by ventilation of the projecting heat-transfer shape 4B on the opposite side to the electronic component 2 can also be performed, and the occurrence of a place where the airflow is hindered on the leeward side of the side wall 4C of the projecting heat-transfer shape 4B can be decreased.

When the vents 4E on the leeward side of the projecting heat-transfer shape 4B are not opened and only the vents 4E on the windward side are opened, or when only the vents 4E on the leeward side are opened and the vents 4E on the windward side are not opened, the air 4H flows passing through the high-temperature portion 4I of the projecting heat-transfer shape 4B on the opposite side to the heat-generating electronic component 2. Consequently, much more heat can be removed from the heat dissipation plate 4 when compared with a case where there is no vent 4E, and the heat dissipation capacity can be improved in such a case.

Not only on the windward side and leeward side but also on the right and left side surfaces of the projecting heat-transfer shape 4B, by additionally providing the vents 4E similar to those described above, the air 4H flows passing through the high-temperature portion 4I of the projecting heat-transfer shape 4B on the opposite side to the heat-generating electronic component 2. Consequently, much more heat can be removed from the heat dissipation plate 4 when compared with the case having no vent 4E, and the heat dissipation capacity can be improved. Furthermore, because an insulation distance between the heat dissipation plate 4 and peripheral electronic components 2 can be kept, the heat 4G generated by the electronic component 2 can be prevented from being absorbed by the peripheral electronic components 2. Further, because the heat 4G is diffused from the heat-transfer surface 4A in four directions and dissipated from the entire heat dissipation plate 4, the same heat dissipation performance can be kept, even when the heat dissipation plate 4 is downsized, when compared with a configuration having no side wall 4C in four directions.

### Second Embodiment

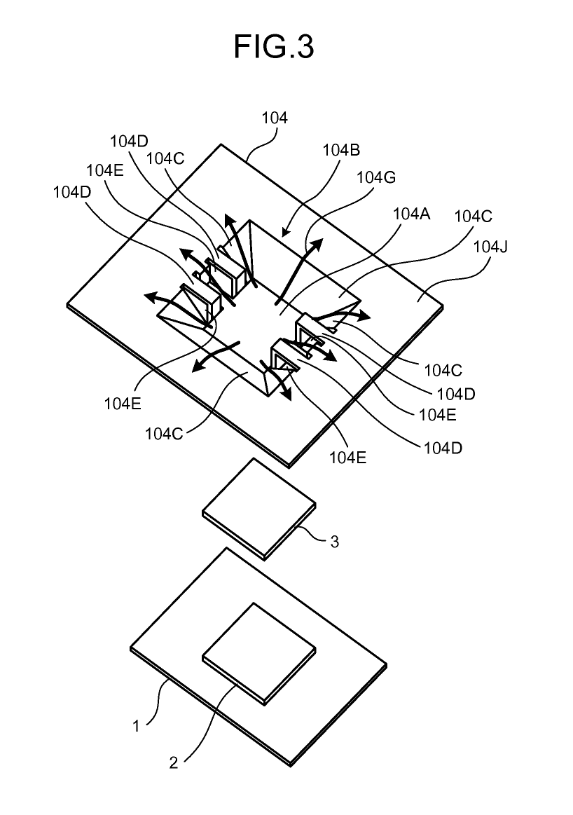

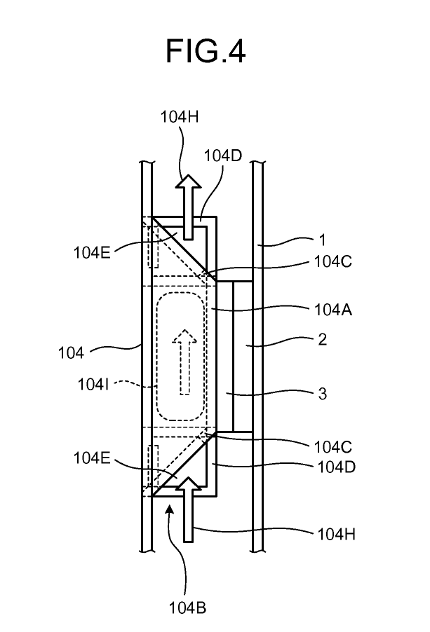

FIG. 3 is an exploded perspective view of a heat dissipation structure of a heat-generating component using a heat dissipation plate according to a second embodiment of the present invention. FIG. 4 is a side view of the heat dissipation structure of the heat-generating component using the heat dissipation plate according to the second embodiment. A projecting heat-transfer shape 104B of a heat dissipation plate 104 according to the second embodiment is adapted for a heat dissipation structure that dissipates heat generated by the electronic component 2 and so as to be contact with the electronic component 2 mounted on the printed board 1 via the thermally-conductive sheet 3. In FIG. 3, heat 104G, schematically represented by an arrow, is transferred from the electronic component 2 to a heat-transfer surface 104A of the heat dissipation plate 104 via the thermally-conductive sheet 3 and then propagates from the heat-transfer surface 104A to a heat-dissipation base surface 104J. In FIG. 4, air 104H, schematically represented by an arrow, dissipates heat generated by the electronic component 2 by penetrating and flowing through the projecting heat-transfer shape 104B. That is, a state where the heat 104G propagates over the entire heat dissipation plate 104 and the flow of the air 104H by convection are illustrated in FIGS. 3 and 4, respectively, to facilitate the explanations. Directions of the printed board 1 and the heat dissipation plate 104 are parallel to the gravitational direction at the time of natural convection; and the directions thereof are not restricted to the gravitational direction at the time of forced convection.

The electronic component 2 is mounted on the printed board 1. The thermally-conductive sheet 3 is sandwiched between the heat-transfer surface 104A of the projecting heat-transfer shape 104B of the heat dissipation plate 104 and the electronic component 2.

A plurality of bent shapes 104D that are formed by alternately repeating a mountain fold and valley fold, as illustrated in FIG. 4, are provided on two side walls 104C facing each other of four side walls 104C of the projecting heat-transfer shape 104B of the heat dissipation plate 104, thereby forming vents 104E. That is, the vents 104E are formed by providing a plurality of slits in the side walls 104C on the windward side and the leeward side to form a plurality of portions sandwiched between the slits and then making the portions sandwiched between the slits such that the bent shapes 104D protruding to the surface side of the heat dissipation plate 104 and the bent shapes 104D protruding to the rear side of the heat dissipation plate 104 are alternately arranged so as to expand each of the slits. The side walls 104C provided with these vents 104E are arranged so as to be positioned on the windward side and the leeward side of the flow of the air 104H for the forced convection. In contrast, the side walls 104C provided with the vents 104E are arranged so as to be positioned vertically for the natural convection.

The heat 104G generated by the electronic component 2 is transferred to the heat dissipation plate 104 via the thermally-conductive sheet 3 and dissipated therefrom. To improve the heat dissipation effect, it is effective if the heat 104G is propagated over the entire heat dissipation plate, i.e., the heat 104G is transferred from the heat-transfer surface 104A to the heat-dissipation base surface 104J. In the heat dissipation structure of the heat-generating component according to the present embodiment, the side walls 104C, formed in four directions of the heat-transfer surface 104A, become the channels required for transferring the heat 104G of the electronic component 2 received by the heat-transfer surface 104A to the heat-dissipation base surface 104J; and thus the heat can be transferred through portions other than the vents 104E in the side walls 104C.

When the vents 104E are opened in a shape capable of allowing passage of a ball with a diameter of 2 millimeters from the surface side to the rear side or from the rear side to the surface side of the heat dissipation plate 104, not only is the heat dissipated by the air 104H flowing from the vents 104E but also the heat is transferred through the side walls 104C other than the vents 104E and dissipated by the entire heat dissipation plate 104, thereby enabling efficient heat dissipation.

The channel for propagation of the heat 104G over the entire heat dissipation plate 104 can have a larger sectional area than that of a channel provided with vents formed by punching, and thus the heat dissipation capacity can be improved. That is, when the vents 4E are formed by punching as done in the first embodiment, a constraint in improvement of the heat dissipation capacity due to a trade-off relation occurs: when the area of the vent 4E is increased in order to improve ventilation of the air 4H, the area of the heat-transfer channel from the heat-transfer surface 4A to the heat-dissipation base surface 4J decreases. In contrast, in the present embodiment, even when the area of the vent 104E is increased, the area of the heat-transfer channel from the heat-transfer surface 104A to the heat-dissipation base surface 104J does not decrease, and thus the heat dissipation capacity can be easily improved.

Consequently, the decrease is prevented in the amount of heat propagated from the projecting heat-transfer shape 104B over the entire heat dissipation plate 104, and the air 104H flowing toward the projecting heat-transfer shape 104B also passes through the vents 104E and flows through a high-temperature portion 104I (a space surrounded by the heat-transfer surface 104A and the side walls 104C, which becomes high temperature due to radiation or the like from the heat-transfer surface 104A and the side walls 104C) of the projecting heat-transfer shape 104B on an opposite side to the heat-generating electronic component 2. Therefore, much more heat can be removed from the heat dissipation plate 104, and the heat dissipation amount can be increased.

Further, the flow of the air 104H occurs also on the leeward side of the projecting heat-transfer shape 104B, and thus an effect to decrease the occurrence of places in which the flow of air after removing heat from the heat dissipation plate 104 is hindered can be obtained, thereby enabling the heat dissipation capacity to be improved.

When the vents 104E on the leeward side of the projecting heat-transfer shape 104B are not opened and only the vents 104E on the windward side are opened, or when only the vents 104E on the leeward side are opened and the vents 104E on the windward side are not opened, the air 104H also flows passing through the high-temperature portion 104I of the projecting heat-transfer shape 104B on the opposite side to the heat-generating electronic component 2. Consequently, much more heat can be removed from the heat dissipation plate 104 than from one with no vent 104E, and the heat dissipation capacity can be improved.

Not only on the windward side and leeward side but also on the right and left side surfaces of the projecting heat-transfer shape 104B, by additionally providing the vents similar to those described above, the air 104H flows passing through the opposite side to the heat-generating electronic component 2 of the projecting heat-transfer shape 104B, which becomes high temperature. Consequently, much more heat can be removed from the heat dissipation plate 104 than from that with no vent 104E, and the heat dissipation capacity can be improved. Furthermore, because an insulation distance can be kept between the heat dissipation plate 104 and the peripheral electronic components, the heat 104G generated by the electronic component 2 can be prevented from being reabsorbed by peripheral electronic components. Further, because the heat 104G is diffused from the heat-transfer surface 104A in four directions and dissipated from the entire heat dissipation plate 104, the same heat dissipation capacity can be kept even when the heat dissipation plate 104 is downsized in comparison with a heat dissipation plate that has no side wall 104C in four directions.

### Third Embodiment

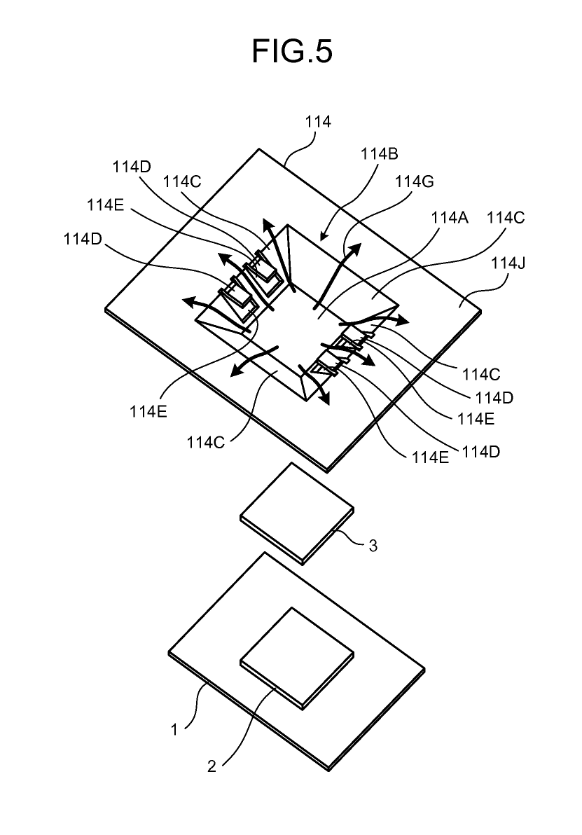

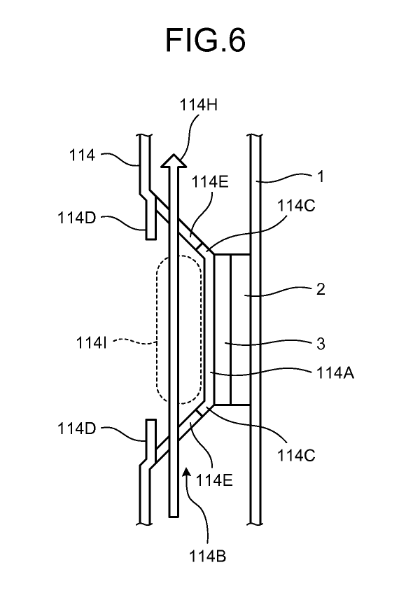

FIG. 5 is an exploded perspective view of a heat dissipation structure of a heat-generating component using a heat dissipation plate according to a third embodiment of the present invention. FIG. 6 is a sectional view of the heat dissipation structure of the heat-generating component using the heat dissipation plate according to the third embodiment. A projecting heat-transfer shape 114B of a heat dissipation plate 114 according to the third embodiment has a heat dissipation structure in which the heat generated by the electronic component 2 is dissipated by being in contact with the electronic component 2 mounted on the printed board 1 via the thermally-conductive sheet 3. In FIG. 5, heat 114G, schematically represented by an arrow, is transferred from the electronic component 2 to a heat-transfer surface 114A of the heat dissipation plate 114 via the thermally-conductive sheet 3 and then propagates from the heat-transfer surface 114A to a heat-dissipation base surface 114J. In FIG. 6, the air 114H, schematically represented by an arrow, dissipates heat generated by the electronic component 2 by penetrating and flowing through the projecting heat-transfer shape 114B. That is, FIGS. 5 and 6 illustrate, to facilitate the explanations, a state where the heat 114G propagates over the entire heat dissipation plate 114 and the flow of the air 114H by convection, respectively. Directions of the printed board 1 and the heat dissipation plate 114 are parallel to the gravitational direction for the natural convection, and the directions thereof are not restricted to the gravitational direction for the forced convection.

As illustrated in FIG. 5, a plurality of standing wall shapes 114D and vents 114E are provided in two side walls facing each other of four side walls 114C of the projecting heat-transfer shape 114B of the heat dissipation plate 114 by bending and raising the side walls 114C by lancing or the like. The side walls 114C provided with these vents 114E are arranged so as to be positioned on the windward side and the leeward side of the flow of the air 114H for the forced convection. In contrast, the side walls 114C provided with the vents 114E are arranged so as to be positioned vertically for the natural convection.

The heat 114G generated by the electronic component 2 is transferred to the heat dissipation plate 114 via the thermally-conductive sheet 3 and dissipated therefrom. To improve the heat dissipation capacity, it is effective if the heat 114G is propagated over the entire heat dissipation plate 114, i.e., the heat 114G is transferred from the heat-transfer surface 114A to the heat-dissipation base surface 114J. In the heat dissipation structure of the heat-generating component according to the present embodiment, the side walls 114C, which function as the channels required to transfer the heat 114G of the electronic component 2 received by the heat-transfer surface 114A to the heat-dissipation base surface 114J, are formed in four directions of the heat-transfer surface 114A, and thus heat can be transferred through portions other than the vents 114E in the side walls 114C.

When the width of the vent 114E is less than 2 millimeters, the air 114H for convection is hard to pass through the vents 114E, and thus the width thereof is set to be equal to or larger than 2 millimeters. When the vent 114E is opened with an area equal to or less than 30% per one side wall 114C of the projecting heat-transfer shape 114B (in other words, when the value acquired by dividing “the sum total of the area of the vents 114E provided in one of the side walls 114C” by “the area of one side wall 114C before forming the vents 114E” becomes 0.3 or less), efficient heat dissipation can be performed. This is because not only does the air 114H flow from the vents 114E to dissipate heat, but also the heat is transferred through the side walls 114C excluding the vents 114E and is dissipated by the entire heat dissipation plate 114.

As illustrated in FIG. 6, by providing the vents 114E in the projecting heat-transfer shape 114B, the air 114H passes through the vents 114E and flows through a high-temperature portion 114I (a space surrounded by the heat-transfer surface 114A and the side walls 114C, which becomes high temperature due to radiation or the like from the heat-transfer surface 114A and the side walls 114C) of the projecting heat-transfer shape 114B on the opposite side to the heat-generating electronic component 2 and the standing wall shapes 114D. Therefore, much more heat can be removed from the heat dissipation plate 114, and the heat dissipation amount can be increased.

Because the air 114H also flows to the leeward side of the projecting heat-transfer shape 114B, an effect to decrease the occurrence of a place in which the flow of air 114H after removing heat from the heat dissipation plate 114 is hindered can be obtained, thereby enabling the heat dissipation capacity to be improved.

When the vents 114E on the leeward side of the projecting heat-transfer shape 114B are not opened and only the vents 114E on the windward side are opened, or when only the vents 114E on the leeward side are opened and the vents 114E on the windward side are not opened, the air 114H flows passing through the high-temperature portion 114I of the projecting heat-transfer shape 114B on the opposite side to the heat-generating electronic component 2. Consequently, much more heat can be removed from the heat dissipation plate 114 than from one with no vent 114E, and the heat dissipation capacity can be improved. Furthermore, because an insulation distance can be kept between the heat dissipation plate 114 and peripheral electronic components, the heat 114G generated by the electronic component 2 is prevented from being reabsorbed by the peripheral electronic components. Further, because the heat 114G is diffused from the heat-transfer surface 114A in four directions and dissipated from the entire heat dissipation plate 114, the same heat dissipation performance can be kept, even when the heat dissipation plate 114 is downsized when compared with one that has no side wall 114C in four directions.

If the vents 114E similar to those described above are added not only on the windward side and leeward side but also on the right and left side surfaces of the projecting heat-transfer shape 114B, the air 114H flows passing through the high-temperature portion 114I of the projecting heat-transfer shape 114B on the opposite side to the heat-generating electronic component 2. Consequently, much more heat can be removed from the heat dissipation plate 114 than from that with no vent 114E, and the heat dissipation capacity can be improved.

### Fourth Embodiment

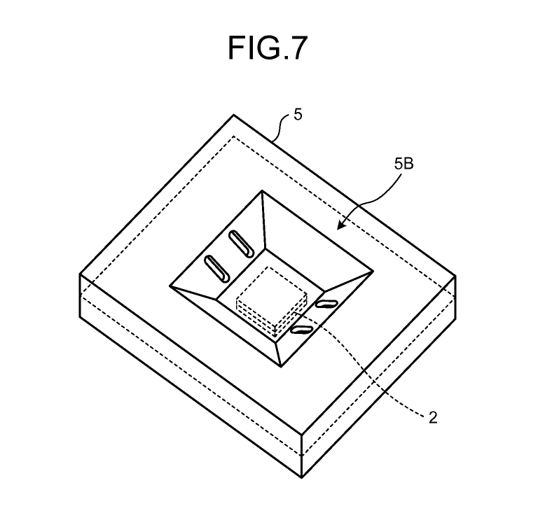

FIG. 7 is an exploded perspective view of a heat dissipation structure of a heat-generating component using a heat dissipation plate according to a fourth embodiment of the present invention. In the fourth embodiment, by providing a projecting heat-transfer shape 5B similar to the projecting heat-transfer shape 4B in the first embodiment on an external casing 5, the heat dissipation plate 4 in the first embodiment is not needed for dissipating the heat generated by the electronic component 2. That is, in a case where the external casing 5 of an electronic device is of a metal plate, the projecting heat-transfer shape 5B can be provided on the external casing 5, and thus a dedicated heat dissipation plate does not need to be provided for dissipating the heat generated by the electronic component 2. Accordingly, the number of components can be reduced, thereby enabling the assembly man-hour and cost to be reduced.

Furthermore, the vents provided in the projecting heat-transfer shape is less limited in the size and depth of the projecting heat-transfer shape compared with a case where the projecting heat-transfer shape is of a U-shape or a tongue shape. Therefore, a size can be set according to a protective structure specification of the electronic device. That is, in order to realize a protective structure that prevents fingers, screws, or the like from slipping into inside the product according to a protection code based on the solid foreign material specified by the International Electrotechnical Commission (IEC), restrictions need to be imposed on the size of an opening width to be a certain value or below (for example, 3 millimeters or below). When the U-shaped or tongue-shaped projecting heat-transfer shape as in the conventional technique is provided on a casing, the opening width increases, thereby making it difficult to realize the protective structure. As in the present embodiment, by providing the projecting heat-transfer shape 5B similar to that of the first embodiment with a plurality of openings on the external casing 5, even when the external casing 5 is integrally formed with the heat dissipation plate, the opening size can be set with matching with the protective structure of the product.

It is assumed here that the projecting heat-transfer shape 5B is similar to the projecting heat-transfer shape 4B of the first embodiment. However, the projecting heat-transfer shape 5B can be similar to the projecting heat-transfer shape 104B of the second embodiment or the projecting heat-transfer shape 114B of the third embodiment.

### Fifth Embodiment

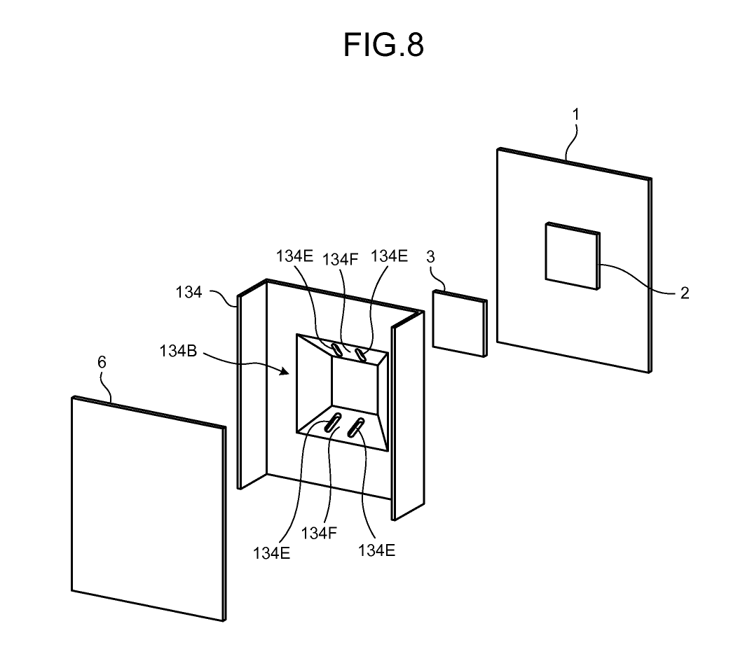

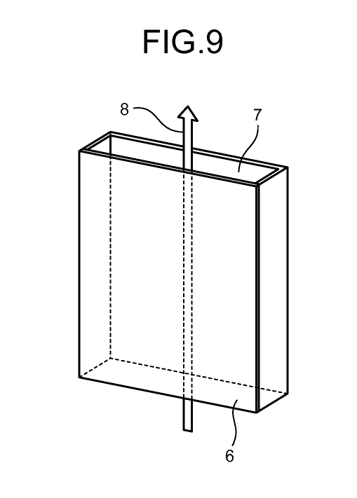

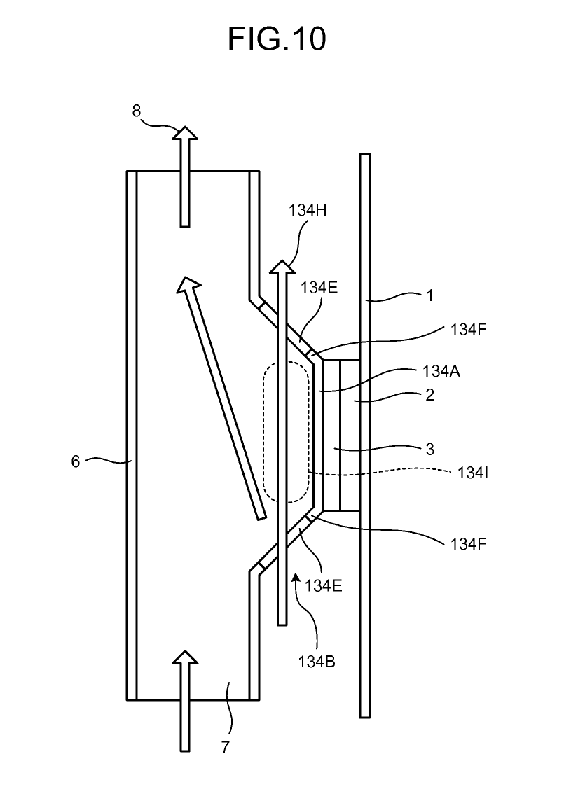

FIG. 8 is an exploded perspective view of a heat dissipation structure of a heat-generating component using a heat dissipation plate according to a fifth embodiment of the present invention. A projecting heat-transfer shape 134B of a heat dissipation plate 134 according to the fifth embodiment is adapted to a structure in which the heat generated by the electronic component 2 is dissipated, by it being brought into contact with the electronic component 2 mounted on the printed board 1 via the thermally-conductive sheet 3. FIG. 9 is a perspective view of the heat dissipation structure of the heat-generating component using the heat dissipation plate according to the fifth embodiment, and illustrates a state where a cylindrical shape 7 is formed by a bent shape of the heat dissipation plate 134 and a cover 6. FIG. 10 is a sectional view of the heat dissipation structure of the heat-generating component using the heat dissipation plate according to the fifth embodiment, and illustrates the flow of air 134H inside the cylindrical shape 7 formed by the bent shape made of the heat dissipation plate 134 and the cover 6 and around the projecting heat-transfer shape 134B. The heat dissipation plate 134 and the printed board 1 here are arranged in parallel to the gravitational direction. Note that the cover 6 does not need to be a dedicated member, and a part of a member (for example, a casing) separate from the heat dissipation plate 134 can be adapted.

In the heat dissipation structure of the heat-generating component using the heat dissipation plate 134 according to the fifth embodiment, a plurality of vents 134E by punching or the like are provided on the two side walls facing each other of the four side walls 134F of the projecting heat-transfer shape 134B of the heat dissipation plate 134. The side walls 134F provided with these vents 134E are arranged so as to be positioned vertically.

As illustrated in FIGS. 9 and 10, a rising air current 8 is generated due to a chimney effect by the cylindrical shape 7 formed by the bent shape of the heat dissipation plate 134 and the cover 6; and the air 134H is sucked out, which flows into the cylindrical shape 7 through the vents 134E of the projecting heat-transfer shape 134B. Therefore, an amount of air increases that passes through a high-temperature portion 134I (a space surrounded by the heat-transfer surface 134A and the side walls 134F, which becomes high temperature due to radiation or the like from the heat-transfer surface 134A and the side walls 134F) increases. Therefore, much more heat can be removed from the heat dissipation plate 134 than those the cylindrical shape 7 are not provided, and the heat dissipation capacity can be improved.

Thus, if the printed board 1 mounted with the electronic component 2 and the heat dissipation plate 134 are parallel to the gravitational direction, the cylindrical shape 7 is formed by providing a wall by a member different from the heat dissipation plate 134 on the opposite side to the electronic component 2 of the projecting heat-transfer shape 134B so as to facilitate the rising current flowing through the vents 134E provided in the side walls 134F of the projecting heat-transfer shape 134B, thereby enabling the heat dissipation amount to be increased.

Note that it is assumed here that the vents 134E are similar to the vents 4E of the first embodiment;

however, the vents 134E can be similar to the vents 104E of the second embodiment or the vents 114E of the third embodiment.

### Sixth Embodiment

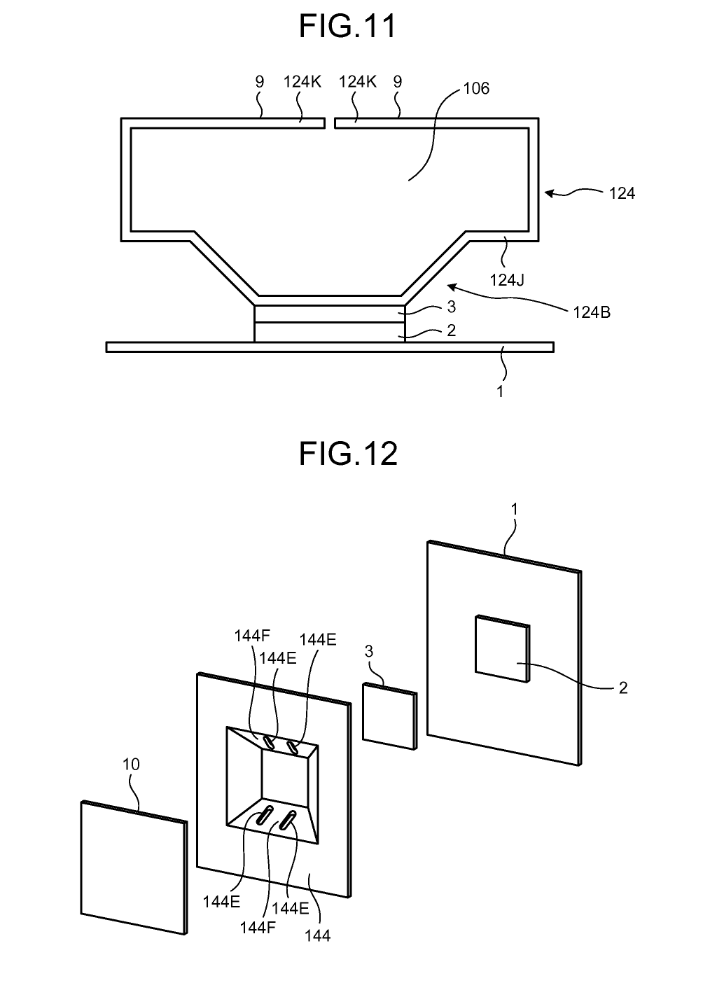

FIG. 11 is a sectional view of a bottom surface of a heat dissipation structure of a heat-generating component using a heat dissipation plate according to a sixth embodiment of the present invention. The heat dissipation structure of a heat-generating component using a heat dissipation plate 124 according to the sixth embodiment includes the printed board 1, the electronic component 2, and the thermally-conductive sheet 3. The difference from the fifth embodiment lies in that a cylindrical shape 106 is formed by a bend 9 of the heat dissipation plate 124 without applying a cover; and the others are the same.

By bending the heat dissipation plate 124 several times so as for the opposite ends 124K of a heat-dissipation base portion 124J of the heat dissipation plate 124 to closely face each other, a chimney-shaped space is formed, through which heated air passes due to convection, by the cylindrical shape 106. It is also possible to form the chimney-shaped space, through which heated air passes by convection, by bending one of the opposite ends 124K of the heat-dissipation base portion 124J of the heat dissipation plate 124 so as to approach the other end 124K.

Consequently, the component number can be reduced, thereby enabling the assembly man-hour and cost to be reduced.

Further, even in a state where another member that can be used as a wall is not present in the vicinity of the heat dissipation plate 124, the cylindrical shape can be formed, which thus enables the heat dissipation plate 124 to be designed in its structure including such as arrangement and size with more improved flexible manner.

In this manner, when the printed board 1 mounted with the electronic component 2 and the heat dissipation plate 124 are in parallel to the gravitational direction, the cylindrical shape 106 is formed on the opposite side to the electronic component of the projecting heat-transfer shape by providing a wall with the bent shape of the heat dissipation plate 124; and the rising current, flowing through the vents provided in the side wall of the projecting heat-transfer shape, is facilitated, thereby enabling the heat dissipation amount to be increased.

### Seventh Embodiment

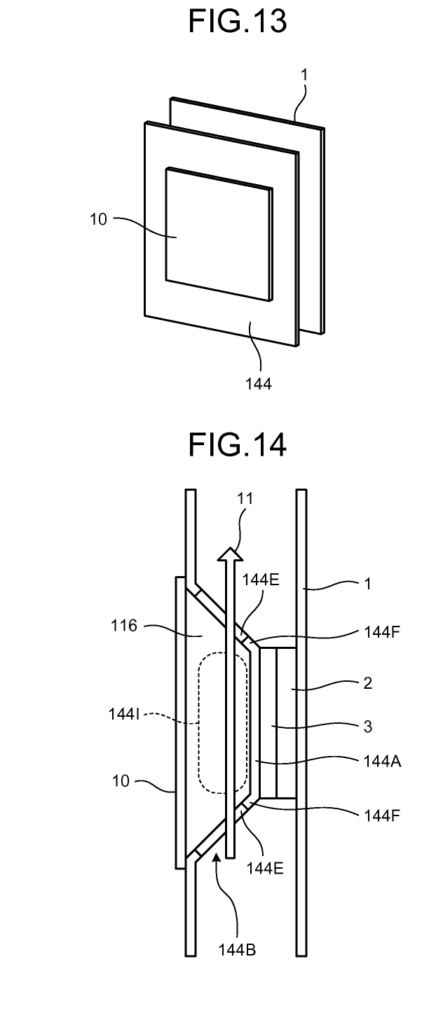

FIG. 12 is an exploded perspective view of a heat dissipation structure of a heat-generating component using a heat dissipation plate according to a seventh embodiment of the present invention. A heat dissipation structure of a heat-generating component using a heat dissipation plate 144 according to the seventh embodiment includes the printed board 1, the electronic component 2, the thermally-conductive sheet 3, and a heat-dissipation cover 10. A projecting heat-transfer shape 144B of the heat dissipation plate 144 comes in contact with the electronic component 2 via the thermally-conductive sheet 3. The electronic component 2 generates heat by energizing electronic devices. FIG. 13 is a perspective view of the heat dissipation structure of the heat-generating component using the heat dissipation plate according to the seventh embodiment, and illustrates a state where the projecting heat-transfer shape 144B of the heat dissipation plate 144 is covered with the heat-dissipation cover 10 from an opposite side to the electronic component 2. FIG. 14 is a sectional view of the heat dissipation structure of the heat-generating component using the heat dissipation plate according to the seventh embodiment, and illustrates a state where the projecting heat-transfer shape 144B of the heat dissipation plate 144 for dissipating heat generated by the electronic component 2 is covered with the heat-dissipation cover 10 from the opposite side to the electronic component 2. Here, the heat dissipation plate 144 and the printed board 1 are arranged in parallel to the gravitational direction.

In a heat dissipation structure of a heat-generating component using the heat dissipation plate 144 of the seventh embodiment, vents 144E similar to those of the first embodiment are provided in two side walls facing each other of four side walls 144F of the projecting heat-transfer shape 144B of the heat dissipation plate 144; and the side walls 144F provided with these vents 144E are arranged to be vertically, or at up and down positions. As illustrated in FIGS. 13 and 14, the projecting heat-transfer shape 144B of the heat dissipation plate is covered with the heat-dissipation cover 10 from the opposite side to the electronic component 2.

Furthermore, as illustrated in FIG. 14, a rising current 11 is generated due to the chimney effect acquired by a cylindrical shape 116, and much more air passes through a high-temperature portion 144I (a space surrounded by a heat-transfer surface 144A, the side walls 144F, and the heat-dissipation cover 10, which becomes high temperature due to radiation or the like from the heat-transfer surface 144A and the side walls 144F) of the projecting heat-transfer shape 144B on the opposite side to the electronic component 2. Therefore, much more heat can be removed from the heat dissipation plate 144 when compared with those with no heat-dissipation cover 10 provided, and the heat dissipation capacity can be improved.

It is assumed here that the vents 144E are similar to those vents 4E of the first embodiment. However, the vents 144E can be similar to those vents 104E of the second embodiment or the vents 114E of the third embodiment.

In the respective embodiments described above, a case has been described where the heat-generating component is the electronic component as an example. Note that, however, the present invention can be applied similarly to a case where the heat-generating component is a resistor or the like.

### INDUSTRIAL APPLICABILITY

As described above, the heat dissipation structure of a heat-generating component according to the present invention is useful for dissipating heat of an electronic component.

### REFERENCE SIGNS LIST

1 printed board, 2 electronic component, 3 thermally-conductive sheet, 4, 104, 114, 124, 134, 144 heat dissipation plate, 4A, 104A, 114A, 134A, 144A heat-transfer surface, 4B, 5B, 104B, 114B, 134B, 144B projecting heat-transfer shape, 4C, 104C, 114C, 134F, 144F side wall, 4E, 104E, 114E, 134E, 144E vent, 4G, 104G, 114G heat, 4H, 104H, 114H, 134H air, 4I, 104I, 114I, 134I, 144I high-temperature portion, 4J, 104J, 114J, 124J heat-dissipation base surface, 5 external casing, 6 cover, 7 cylindrical shape, 8 rising current, 9 bend, 10 heat-dissipation cover, 104D bent shape, 114D standing wall shape, 124K end.

1. A heat dissipation plate comprising:
a substantially rectangular heat transfer surface that comes in contact with a heat-generating component;
a plurality of side walls that are provided respectively in four directions of the heat transfer surface; and
a heat-dissipation base surface that is connected to the heat transfer surface via the side walls, wherein
heat generated by the heat-generating component
is received by the heat transfer surface,
is transmitted from the heat transfer surface to the heat-dissipation base surface via the plurality of side walls, and
is dissipated from the heat-dissipation base surface, and
a plurality of slits are provided on at least one of the side walls, and
bent shapes protruding to a surface side and bent shapes protruding to a rear side are formed and alternately arranged on portions between the slits so as to form vents.

2. The heat dissipation plate according to claim 1, wherein
the plurality of the vents are provided respectively on two side walls facing each other, with the heat transfer surface being set therebetween, of the plurality of the side walls.

3. (canceled)

4. A heat dissipation plate comprising:
a substantially rectangular heat transfer surface that comes in contact with a heat-generating component;
a plurality of side walls that are provided respectively in four directions of the heat transfer surface; and
a heat-dissipation base surface that is connected to the heat transfer surface via the side walls, wherein
a plurality of vents are formed by providing a plurality of bent and raised portions on at least one of the side walls.

5. The heat dissipation plate according to claim 1, wherein
a cover is provided to form a cylindrical space between the heat transfer surface and the cover on a surface opposite to a side coming in contact with the heat-generating component, and
the cover, in a case where a printed board on which the heat-generating component is mounted is arranged in parallel to a gravitational direction, generates an air current that passes through a space surrounded by the heat transfer surface and the side walls and the cylindrical space due to a chimney effect.

6. The heat dissipation plate according to claim 1, wherein
a cylindrical space is formed on a surface opposite to a side coming in contact with the heat-generating component by bending the heat-dissipation base portion, and
in a case where a printed board on which the heat-generating component is mounted is arranged in parallel to a gravitational direction, an air current, which is generated due to a chimney effect, passes through a space surrounded by the heat transfer surface and the side walls and the cylindrical space.

7. The heat dissipation plate according to claim 1, wherein
a heat-dissipation cover is provided on a surface opposite to a side coming in contact with the heat-generating component, and
the heat-dissipation cover generates an air current that passes through a space surrounded by the heat transfer surface and the side walls due to a chimney effect, in a case where a printed board on which the heat-generating component is mounted is arranged in parallel to a gravitational direction.

8. The heat dissipation plate according to claim 1, wherein
the heat dissipation plate is a part of a casing of an electronic device including the heat-generating component.

9. The heat dissipation plate according to claim 4, wherein
the heat dissipation plate is a part of a casing of an electronic device including the heat-generating component.
